(19) United States
(12) Patent Application Publication
(10) Pub. No.: US 2013/0113353 A1
(43) Pub. Date: May 9, 2013

(54) HOUSEHOLD APPLIANCE INCLUDING SNAP-ON TOE KICK PANEL

(71) Applicants: Casey Carr, New Bern, NC (US); Michael Justis, New Bern, NC (US)

(72) Inventors: Casey Carr, New Bern, NC (US); Michael Justis, New Bern, NC (US)

(73) Assignee: BSH HOME APPLIANCES CORPORATION, Huntington Beach, CA (US)

(21) Appl. No.: 13/288,048

(22) Filed: Nov. 3, 2011

(51) Int. Cl. H05K 5/02; B23P 19/02

(52) U.S. Cl. 312/293.3; 29/525

(57) ABSTRACT

A household appliance including a frame defining a cavity at a bottom of the household appliance and a toe-kick panel structured to cover electrical components of the household appliance housed in the cavity. In an exemplary embodiment of the invention, the toe-kick panel includes at least one snap-on connector to secure the toe-kick panel to the frame. The invention also includes a method for attaching the toe-kick panel to the household appliance.

### BACKGROUND OF THE INVENTION

1. Field of the Invention

The present invention relates to a household appliance and more particularly, to a household appliance including a snap-on toe kick panel and a method thereof that prevents a user of the household appliance from coming into contact with any electrical connections of the household appliance and provides for easier maintenance access.

2. Related Art

In the related art, household appliances, such as dishwashers, include a cavity at the bottom of the machine that is used to house electrical components and connections of the household appliance. In some configurations, the cavity may be designed such that its front portion is recessed rearward from the front frame of the household appliance, enabling a user to stand close to the front of the household appliance wherein their feet can fit into the recessed space, thus allowing the user to be positioned closer to the appliance controls than would otherwise be the case without the recess. In other configurations, the cavity housing, the electrical components and connections may be flush with the cabinet, but is still placed at a position where a user's feet may approach the household appliance. Since the electrical components and connections may cause some safety issues if a user comes into contact with them, a toe-kick panel is used to protect the user from contact with the electrical components and connections. However, when maintenance or repair is needed on the household appliance, it is often necessary to access the cavity and associated electrical components and connections, in which case the toe-kick panel is required to be removed. In the related art, for safety purposes, the toe-kick panel is often screwed to the frame of the dishwasher so that the toe-kick panel is not accidentally or easily removed by, for example, a small child. However, this attachment method adds costs and complexity in both manufacturing of the household appliance and in the removal of the toe-kick panel during maintenance or repair.

The present invention introduces a household appliance with a snap-on toe-kick panel. The snap-on toe kick panel design allows for both secure fastening of the toe-kick panel to avoid accidental removal for safety purposes, as well as removes the need for a multitude of tools to remove the snap-on toe kick panel during maintenance or repair.

### SUMMARY OF THE INVENTION

A first aspect of the present invention is directed to a household appliance. The household appliance may include a frame defining a cavity at a bottom of the household appliance, and a toe-kick panel structured to cover electrical components of the household appliance housed in the cavity. In an exemplary embodiment of the invention, the toe-kick panel includes at least one snap-on connector to secure the toe-kick panel to the frame.

A second aspect of the present invention is directed a method for attaching a toe-kick panel to a household appliance. In an exemplary embodiment, the method comprises at least the step of securing a toe-kick panel to a frame of the household appliance using a snap-on connector formed on or attached to the toe-kick panel.

The illustrative aspects of the present invention are designed to solve the problems herein described and other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various exemplary embodiments of the disclosure, in which:

FIG. 1 depicts a household appliance including a toe-kick panel according to an exemplary embodiment of the invention;

FIG. 2 depicts a toe-kick panel including a snap-on connector according to an exemplary embodiment of the invention;

FIG. 3 depicts a toe-kick panel including a snap-on connector according to an exemplary embodiment of the invention; and

FIG. 4 depicts a method for attaching the toe-kick panel to the household appliance.

The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION OF THE INVENTION

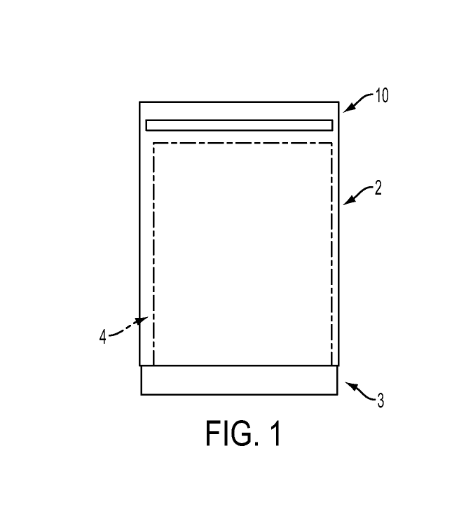

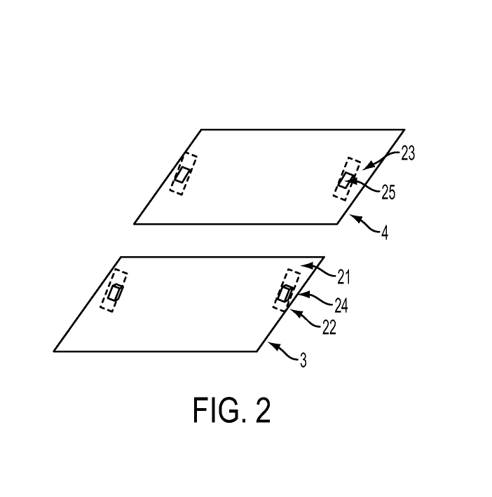

FIG. 1 shows an exemplary embodiment of a household appliance of the present invention, such as a dishwasher 10. The dishwasher 10 may comprise a door 2 which is suitable for tiltable opening. On the lower side of the door 2, the dishwasher 10 may include a toe-kick panel 3. The toe-kick panel 3 may protect a user of the dishwasher 10 from inadvertently accessing a space where the electronics and other functional components (not shown) of the dishwasher 10 may be located, thereby protecting both the user for safety purposes and the electronic components from damage. The toe-kick panel 3 may include at least one snap-on connector 21 (FIG. 2) to secure the toe-kick panel 3 to a frame 4.

While exemplary embodiments of snap-on connectors are described below, it should be understood that the invention is not limited to these embodiments and it is envisioned that any snap-on connector configuration known in the art that allows for joining the toe-kick panel 3 to the frame 4 may be used.

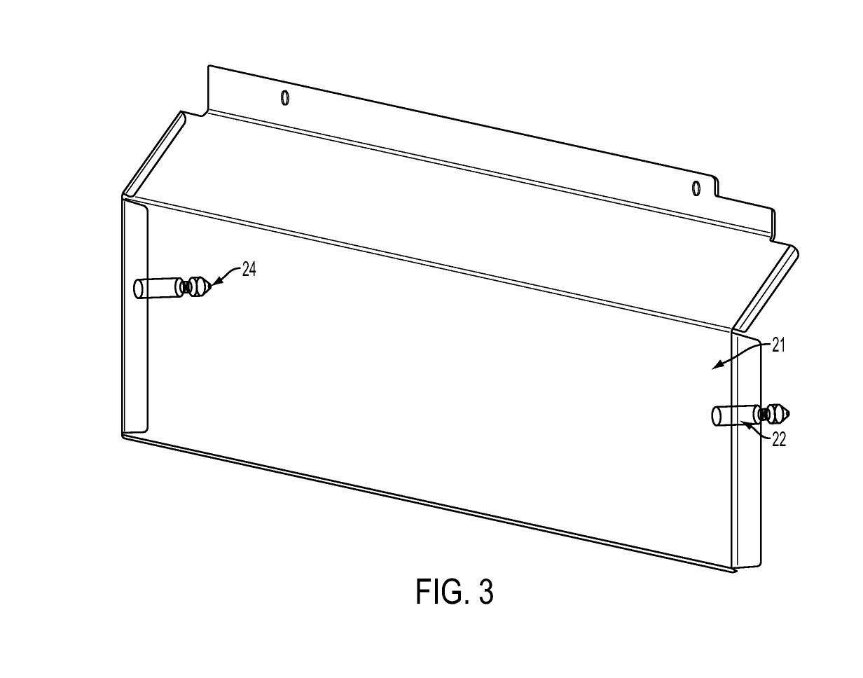

As shown in FIGS. 2 and 3, in an exemplary embodiment, the toe-kick panel 3 may include two of the snap-on connectors 21 disposed on either side of the toe-kick panel 3. Of course, in an alternative configuration, one or more of the snap-on connectors 21 may be disposed on at least one of a top or a bottom of the toe-kick panel 3.

The snap-on connector 21 may include one or more projections 22 that are formed from a resilient material. The projections 22 may engage with the frame 4 via one or more recesses 23 of the frame 4 into which the one or more projections 22 engage. The recesses 23 may also be formed from a resilient material.

In an exemplary embodiment as shown in FIG. 2, the projections 22 may include a locking mechanism 24, such as a resilient tab, to secure the projections 22 to the recesses 23. In this embodiment, the recesses 23 may include a slot or hole 25 in which the resilient tab 24 locks into when the projections 22 are inserted into the recesses 23. The resilient tab 24, accordingly, may be released by compressing the resilient tab 24 from the slot or hole 25. In this case, the resilient tab 24 may include a mating portion that is operable to mate with a tool (not shown) used to compress the resilient tab 24 to unsecure the toe-kick panel 3 from the frame 4.

As shown in the embodiment of FIG. 3, the projections 22 may include a locking mechanism 24, including a section that is compressible from a first diameter greater than an aperture diameter of the recesses 23 to a second diameter that is smaller than the aperture diameter of the recesses 23, to secure the projections 22 to the recesses 23.

In another embodiment, the one or more recesses may be disposed at an angle of approximately 90° counterclockwise to the initial insertion direction of the resilient tab to allow for additional connecting and safety features such as the use of a retaining ring or quick-connect.

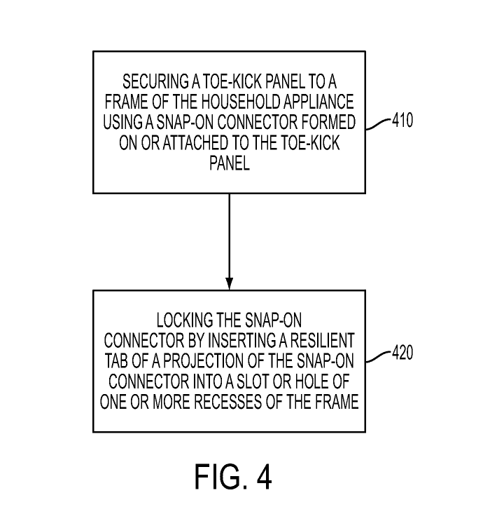

An exemplary method of the invention is depicted in FIG. 4. The method may include at least the steps of securing a toe-kick panel to a frame of the household appliance using a snap-on connector formed on or attached to the toe-kick panel (step 410). At step 420, the snap-on connector may be locked by inserting a resilient tab of a projection of the snap-on connector into a slot or hole of one or more recesses of the frame.

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed is:

1. A household appliance, comprising:
a frame defining a cavity at a bottom of the household appliance; and
a toe-kick panel structured to cover electrical components of the household appliance housed in the cavity, wherein the toe-kick panel includes at least one snap-on connector to secure the toe-kick panel to the frame.

2. The household appliance according to claim 1, wherein the toe-kick panel includes two of the at least one snap-on connectors disposed on either side of the toe-kick panel.

3. The household appliance according to claim 1, wherein the at least one snap-on connector is disposed on at least one of a top and a bottom of the toe-kick panel.

4. The household appliance according to claim 1, wherein the at least one snap-on connector includes one or more projections.

5. The household appliance according to claim 4, wherein the one or more projections are formed from a resilient material.

6. The household appliance according to claim 4, wherein the frame includes one or more recesses into which the one or more projections engage.

7. The household appliance according to claim 6, wherein one or more projections engage the one or more recesses in a friction fit.

8. The household appliance according to claim 6, wherein the one or more recesses are formed from a resilient material.

9. The household appliance according to claim 6, wherein the one or more projections include a locking mechanism to secure the one or projections to the one or more recesses.

10. The household appliance according to claim 9, wherein the locking mechanism comprises a resilient tab.

11. The household appliance according to claim 10, wherein the one or more recesses include a slot or hole in which the resilient tab locks into when the one or more projections are inserted into the one or more recesses.

12. The household appliance according to claim 11, wherein the locking mechanism is structured to release by compressing the resilient tab from the one or more recesses.

13. The household appliance according to claim 11, wherein the one or more recesses are disposed at an angle of approximately 90° counterclockwise to the initial insertion direction of the resilient tab.

14. The household attachment according to claim 10, wherein the resilient tab includes a mating portion that is operable to mate with a tool used to unsecure the toe-kick panel from the frame.

15. A method for attaching a toe-kick panel to a household appliance, the method comprising the steps of:
securing a toe-kick panel to a frame of the household appliance using a snap-on connector formed on or attached to the toe-kick panel.

16. The method for attaching a toe-kick panel to a household appliance according to claim 15, wherein the toe-kick panel is secured to the household appliance by engaging one or more projections of the at least one snap-on connector with a recess of the frame.

17. The method for attaching a toe-kick panel to a household appliance according to claim 16, further comprising locking the snap-on connector by inserting a resilient tab of the one or more projections into a slot or hole of the one or more recesses of the frame.

18. The method for attaching a toe-kick panel to a household appliance according to claim 16, wherein the engagement is by a friction fit.

19. The method for attaching a toe-kick panel to a household appliance according to claim 16, further comprising unsecuring the toe-kick panel from the frame using a tool.

20. The method for attaching a toe-kick panel to a household appliance according to claim 19, wherein the tool mates with a resilient tab of the one or more projections.
